(19) United States
(12) Patent Application Publication
(10) Pub. No.: US 2015/0187676 A1
(43) Pub. Date: Jul. 2, 2015

(54) ELECTRONIC COMPONENT MODULE

(71) Applicant: SAMSUNG ELECTRO-MECHANICS CO., LTD., Suwon-Si (KR)

(72) Inventors: Jun Goo WON, Suwon-Si (KR); Sung Hwan PARK, Suwon-Si (KR); Myeong Woo HAN, Suwon-Si (KR); Hyo Gun BAE, Suwon-Si (KR); Youn Suk KIM, Suwon-Si (KR); Ki Joong KIM, Suwon-Si (KR)

(73) Assignee: SAMSUNG ELECTRO-MECHANICS CO., LTD., Suwon-Si (KR)

(21) Appl. No.: 14/259,090

(22) Filed: Apr. 22, 2014

(30) Foreign Application Priority Data
Dec. 27, 2013 (KR) 10-2013-0165429

(51) Int. Cl. H01L 23/367; H01L 23/15; H01L 23/31; H01L 23/522

(52) U.S. Cl. CPC H01L 23/367; H01L 23/5226; H01L 23/15; H01L 23/3121

(57) ABSTRACT

An electronic component module may include a substrate configured to have a cavity formed therein, and an electronic component embedded in the cavity while being attached to one surface of the heat radiating plate. The electronic component module may significantly decrease effects of element interference and electromagnetic wave interference between electronic components by forming a wiring pattern above a cavity.

### CROSS-REFERENCE TO RELATED APPLICATION

This application claims the benefit of Korean Patent Application No. 10-2013-0165429 filed on Dec. 27, 2013, with the Korean Intellectual Property Office, the disclosure of which is incorporated herein by reference.

### BACKGROUND

The present disclosure relates to an electronic component module.

Market demand for portable terminals has recently increased in the field of electronic products. Therefore, processes of miniaturization and lightening of electronic components mounted in electronic products have been required on an on-going basis.

In order to realize the miniaturization and lightening of electronic components, various types of technology, such as system on chip (SOC) technology for implementing a plurality of individual elements on a single chip, system in package (SIP) technology for integrating a plurality of individual elements in a single package, and the like, as well as technology for reducing respective sizes of the mounted components, are required.

Particularly, heat generating elements such as a transmitting amplifier have been gradually miniaturized while having improved performance implemented therein. Since this means that a great deal of heat is radiated from a surface region which has been continuously reduced in size, an electronic component module capable of efficiently radiating heat has been urgently demanded in order to significantly decrease changes in characteristics resulting from temperature deviations caused by a heating phenomenon.

In a case of an electronic component module according to the related art, an electronic component is mounted in a cavity of a substrate and a metal cover is adhered thereto for the sealing thereof, such that heat generated by the electronic component is radiated outwardly from the metal cover. However, since the electronic component module according the related art transfers the heat radiated from a heat generating element to a metal through the air, it may be relatively difficult to effectively radiate the heat in a short space of time.

### SUMMARY

An exemplary embodiment in the present disclosure may provide an electronic component module capable of efficiently radiating heat generated from a semiconductor chip by directly attaching the semiconductor chip to a heat radiating plate.

An exemplary embodiment in the present disclosure may also provide an electronic component module capable of significantly decreasing effects of element interference and electromagnetic wave interference between electronic components by forming a wiring pattern above a cavity.

According to an exemplary embodiment in the present disclosure, an electronic component module may include: a substrate having a cavity formed therein; a heat radiating plate disposed on an opening of the cavity; and an electronic component embedded in the cavity while being attached to one surface of the heat radiating plate.

The electronic component may be connected to an upper internal surface of the cavity by flip-chip bonding.

The substrate may include a wiring pattern formed above the cavity.

The substrate may have at least one heat radiating via having one end electrically connected to the heat radiating plate and the other end exposed ouwardly of the substrate.

The substrate may be a ceramic substrate and the electronic component embedded in the cavity may be a monolithic microwave integrated circuit (MMIC).

The substrate may include at least one passive element mounted on an upper surface thereof.

The substrate may further include a sealing part enclosing the passive element mounted on the upper surface of the substrate and covering an upper portion of the substrate.

According to an exemplary embodiment in the present disclosure, an electronic component module may include: a substrate having a first cavity formed therein; a heat radiating plate having a second cavity formed therein and disposed such that the first cavity and the second cavity are placed in opposite directions from each other; and an electronic component embedded in the second cavity and attached to one surface of the heat radiating plate.

The electronic component may be connected to one surface of the substrate by flip-chip bonding.

The substrate may include a wiring pattern formed to be parallel to one surface of the electronic component.

The substrate may have at least one heat radiating via having one end electrically connected to the heat radiating plate and the other end exposed ouwardly of the substrate.

The substrate may be a ceramic substrate and the electronic component embedded in the cavity may be a monolithic microwave integrated circuit (MMIC).

The substrate may include at least one passive element mounted on an upper surface thereof.

The substrate may further include a sealing part enclosing the passive element mounted on the upper surface of the substrate and covering an upper portion of the substrate.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a perspective view illustrating an example of an electronic component module according to an exemplary embodiment of the present disclosure;

FIG. 2 is a perspective view illustrating a bottom surface of the electronic component module shown in FIG. 1;

FIG. 3 is a cross-sectional view of the electronic component module taken along line A-A′ of FIG. 1;

FIGS. 4 through 8 are cross-sectional views illustrating a method of manufacturing an electronic component module according to an exemplary embodiment of the present disclosure; and

FIG. 9 is a cross-sectional view illustrating a cross-section of an electronic component module according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

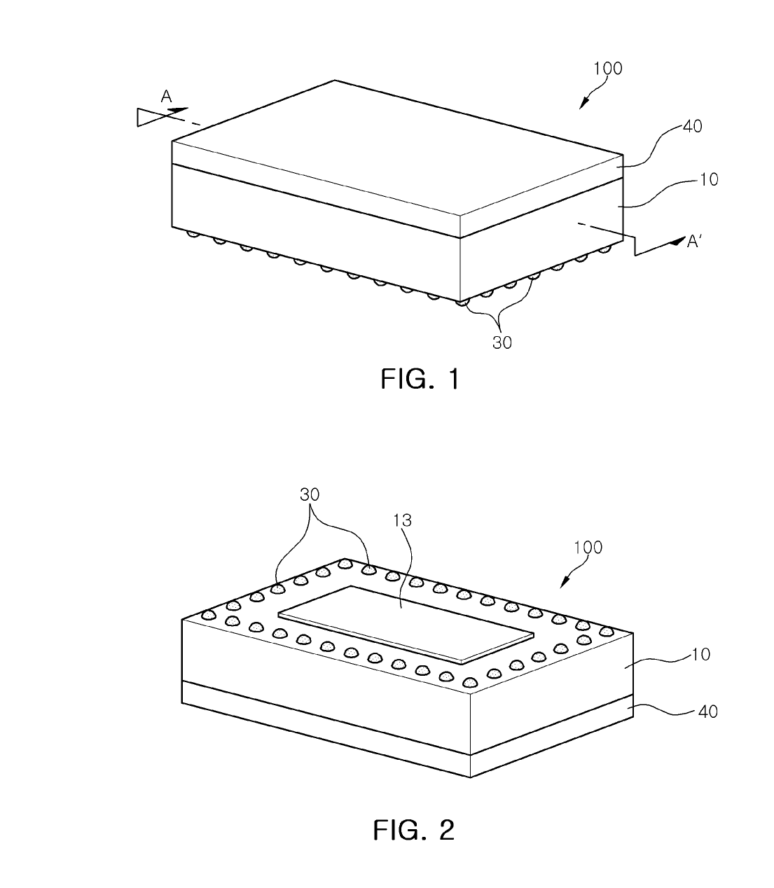

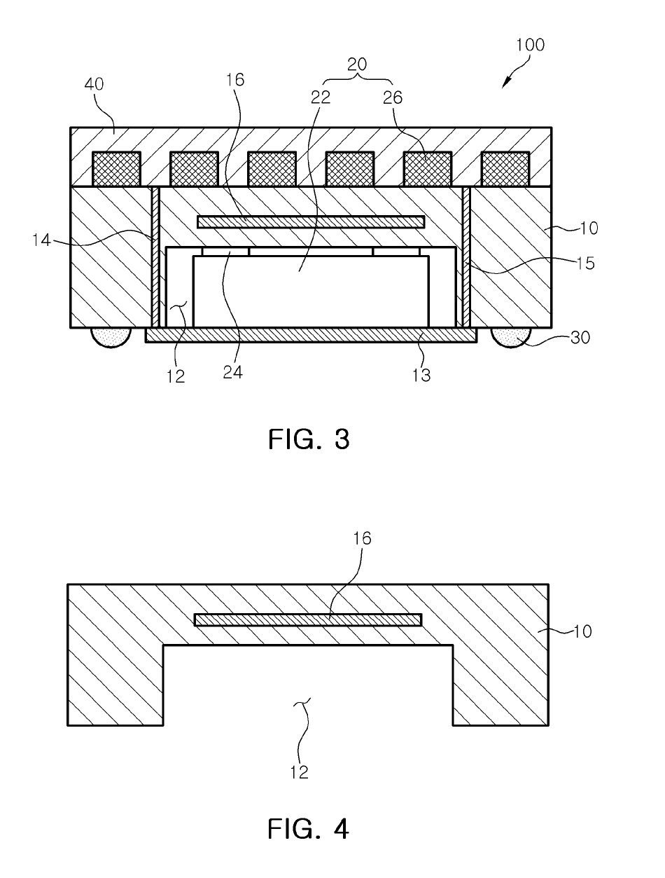

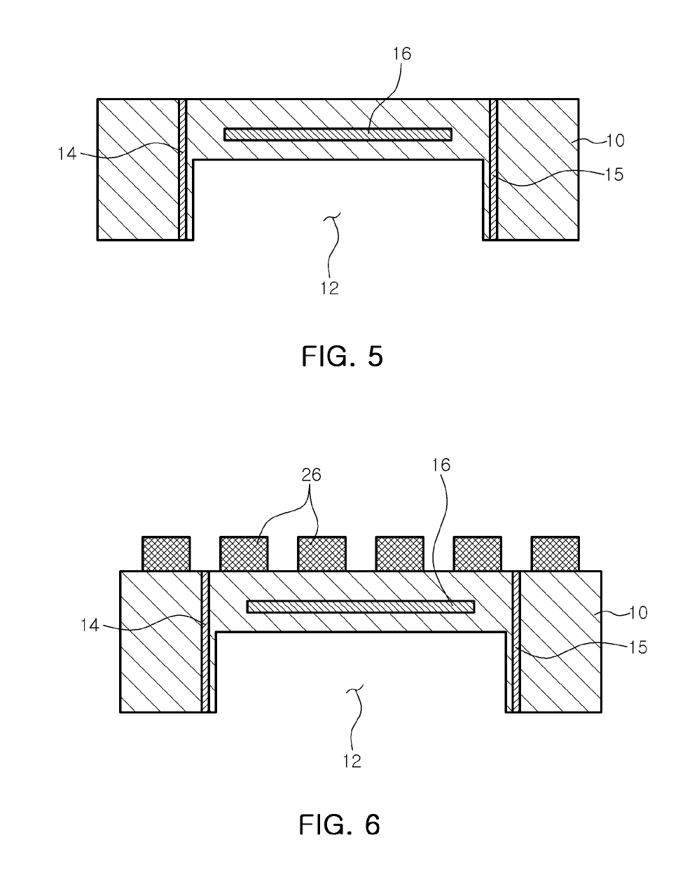

FIG. 1 is a perspective view illustrating an example of an electronic component module according to an exemplary embodiment of the present disclosure. FIG. 2 is a perspective view illustrating a bottom surface of the electronic component module shown in FIG. 1. FIG. 3 is a cross-sectional view of the electronic component module taken along line A-A′ of FIG. 1.

Referring to FIGS. 1 through 3, an electronic component module 100 according to an exemplary embodiment of the present disclosure may include electronic components 20, a substrate 10, connecting terminals 30, and a sealing part 40.

The electronic components 20 may include various electronic elements such as a passive element and an active element, and, as long as the elements may be mounted on the substrate 10 or be embedded in the substrate 10, they may be used as the electronic components 20.

Particularly, the electronic components 20 according to an exemplary embodiment of the present disclosure may include an active element to be embedded in the substrate 10, that is, a semiconductor chip 22, and passive elements 26 mounted outside the substrate 10.

Here, the exemplary embodiment of the present disclosure exemplifies a case in which the semiconductor chip 22 is embedded in the substrate 10 and all of the passive elements 26 are mounted outside the substrate 10. However, the present disclosure is not limited thereto.

That is, the passive elements 26 may also be embedded in the substrate 10 and the semiconductor chip 22 may also be mounted outside the substrate 10, if necessary.

A plurality of semiconductor chips 22 may be provided according to an exemplary embodiment of the present disclosure. By way of example, the semiconductor chip 22 may be a chip for a monolithic microwave integrated circuit (MMIC).

The semiconductor chip 22 may be attached to one surface of a heat radiating plate 13 and may be electrically connected to the substrate 10 by a flip-chip bonded part 24. In this case, an adhesive layer (not shown) may be interposed between the semiconductor chip 22 and one surface of the heat radiating plate 13.

Meanwhile, according to an exemplary embodiment of the present disclosure, as shown in FIG. 3, the semiconductor chip 22 may be electrically connected to the substrate 10 by the flip-chip bonded part 24. However, the present disclosure is not limited thereto. For example, the semiconductor chip 22 may be electrically connected to the substrate 10 by a bonding wire.

The substrate 10 may be a ceramic substrate. However, the substrate is not limited thereto, and various kinds of substrates (for example, a printed circuit board (PCB), a glass substrate, a silicon substrate, a flexible substrate, or the like) well known in the art may be used therefor.

The substrate 10 may include mounting electrodes (not shown) for mounting the electronic components 20 or circuit patterns (not shown) for electrically connecting the mounting electrodes, the mounting electrodes and the circuit patterns being formed on an upper surface of the substrate 10.

In addition, the substrate 10 may be a multilayer substrate including a plurality of layers, and a wiring pattern 16 for forming an electrical connection or conductive vias 14 and 15 may be formed between the respective layers.

Here, the wiring pattern 16 or the circuit patterns (not shown) may be formed above a cavity 12.

In a case in which the circuit patterns (not shown) or the wiring pattern 16 is intensively formed above the cavity of the substrate 10, element interference and electromagnetic wave interference between the electronic components 20 may be suppressed by the wiring pattern 16 or the circuit patterns (not shown).

Particularly, the substrate 10 according to an exemplary embodiment of the present disclosure may include the cavity 12 therein. The semiconductor chip 22 described above may be seated in the cavity 12. In addition, the heat radiating plate 13 for radiating heat generated by the semiconductor chip 22 may be disposed on an opening of the cavity 12.

The substrate 10 may have a plurality of the connecting terminals 30 formed on a lower surface thereof.

The connecting terminals 30 may electrically and physically connect the substrate 10 to a main substrate (not shown) on which the substrate 10 is mounted. Each of the connecting terminals 30 may be variously formed such as having an electrode pad form, a bump form, a solder ball form, or the like, if necessary.

The heat radiating plate 13 may be seated on the opening of the cavity 13 formed in the substrate 10 as described above and may be fastened to the substrate 10.

The heat radiating plate 13 may radiate the heat generated from the semiconductor chip 22 outwardly. In addition, the heat radiating plate 13 may protect the semiconductor chip 22 disposed in the cavity 12 from the outside and may shield electromagnetic waves.

The heat radiating plate 13 may be formed of a material having high thermal conductivity and excellent durability. In addition, the heat radiating plate 13 may be formed of a material having rigidity capable of maintaining a flat shape thereof. For example, as the heat radiating plate 13, a metal plate may be used.

However, the present disclosure is not limited thereto. For example, the heat radiating plate 13 may be formed by forming a metal plating layer on a resin material, or the like, or a resin plate including a conductive powder may be used therefor.

A heat radiating via 15 may have one end thereof electrically connected to the heat radiating plate 13 and the other end thereof exposed outwardly of the substrate 10.

However, the substrate 10 according to an exemplary embodiment of the present disclosure is not limited to including the configuration of the heat radiating via 15, but may be configured in various manners, as long as the heat of the heat radiating plate 13 may be easily radiated.

Therefore, even in a case in which an element (e.g., a power amplifying element) having high heat value is used, the semiconductor chip 22 according to an exemplary embodiment of the present disclosure may easily radiate the heat generated by the semiconductor chip 22.

In addition, the heat radiating plate 13 may be adhered to the substrate 10 using an adhesive or a method such as a welding method, or the like.

The sealing part 40 may be provided to safely protect the electronic components 20 mounted on the substrate 10 from external impacts.

To this end, the sealing part 40 may be formed to enclose the entirety of an upper portion of the substrate 10 so as to receive the electronic components 20 mounted on the substrate 10 therein and may seal the electronic components 20 provided on the substrate 10 therein.

The sealing part 40 may be formed by a molding method. In this case, an epoxy molding compound (EMC) may be used as a material of the sealing part 40.

However, the present disclosure is not limited thereto. That is, various formation methods such as a printing method, a spin coating method, a jetting method, and the like may be used for forming the sealing part 40, if necessary.

Hereinafter, a method of manufacturing an electronic component module according to an exemplary embodiment of the present disclosure will be described.

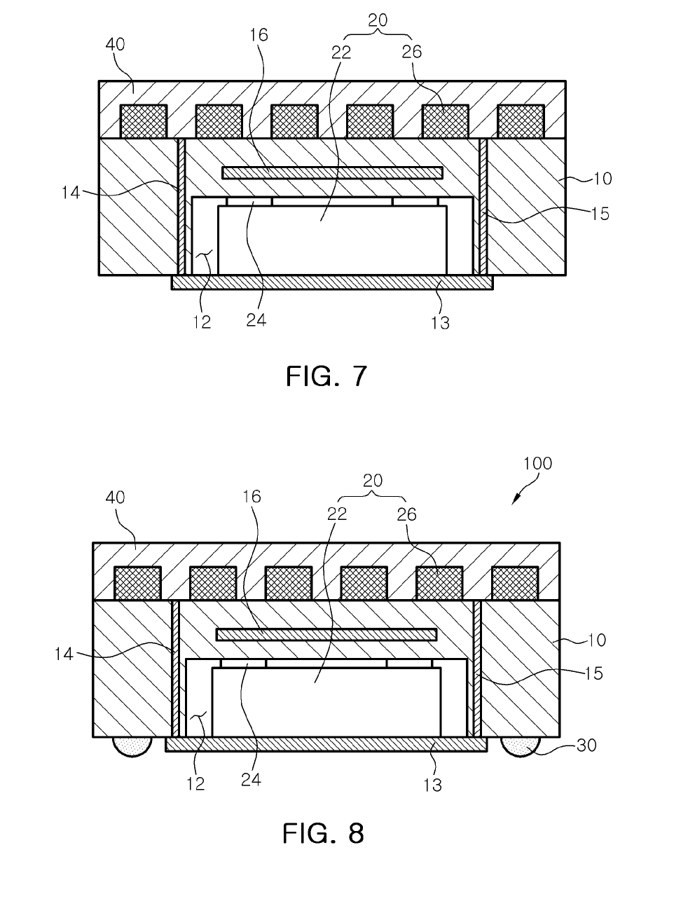

FIGS. 4 through 8 are cross-sectional views illustrating a method of manufacturing an electronic component module according to an exemplary embodiment of the present disclosure.

Referring to FIGS. 4 through 8, in the method of manufacturing an electronic component module according to the exemplary embodiment of the present disclosure, as shown in FIG. 4, an operation of forming the cavity 12 in the substrate 10 may be performed.

The substrate 10 according to an exemplary embodiment of the present disclosure may be a ceramic substrate. However, the present disclosure is not limited thereto. In addition, the substrate 10 may be a multilayer circuit substrate formed of a plurality of layers, and the respective layers may be electrically connected to each other by the wiring pattern 16.

Next, as shown in FIG. 5, an operation of forming mounting electrodes (not shown), the conductive vias 14 and 15, and like on the substrate 10 may be performed.

Here, in a case in which the substrate 10 according to an exemplary embodiment of the present disclosure is the ceramic substrate, the wiring pattern and the vias are formed on ceramic green sheets and subsequently, are sintered, such that the substrates 10 having the conductive vias 14 and 15 formed thereon may be collectively manufactured.

Next, an operation of mounting the electronic components 20 on the substrate 10 may be performed. As shown in FIG. 6, an exemplary embodiment of the present disclosure shows a case in which the electronic components 20 are first mounted on the upper surface of the substrate 10.

In this case, various types of passive elements 26 and active elements (not shown) may be mounted on the upper surface of the substrate 10.

Next, an operation of mounting the semiconductor chip 22 in the cavity 12 opened through a lower surface of the substrate 10 may be performed.

According to the operation of mounting the semiconductor chip 22 in the cavity 12, as shown in FIG. 7, the semiconductor chip 22 may be first adhered to the heat radiating plate 13, the semiconductor chip 22 adhered to the heat radiating plate 13 may be seated in the cavity 12, and then, the semiconductor chip 22 and the substrate 10 may be connected to each other by the flip-chip bonded part 24.

In this case, the heat radiating plate 13 may be disposed on the opening of the cavity 12. In addition, the heat radiating plate 13 may be electrically and physically connected to the heat radiating via 15. To this end, the heat radiating plate 13 may be adhered to the substrate 10 using a conductive adhesive, or the like.

Once all of the electronic components 20 are mounted on the substrate 10 by the operations described above, an operation of forming the sealing part 40 may then be performed as shown in FIG. 7.

The sealing part 40 may be formed to cover the upper portion of the substrate 10 and enclosing the passive elements 26 mounted on the upper surface of the substrate 10 therein.

Meanwhile, in a case in which the connecting terminal 30 (see FIG. 1) of the electronic component module 100 according to an exemplary embodiment of the present disclosure is formed to have a pad shape, the connecting terminal 30 may be already formed during the operation of FIG. 5 forming the substrate 10.

On the other hand, in a case in which the connecting terminal 30 is formed to have a solder ball or bump shape, after the operation of mounting the semiconductor chip or the operation of forming the sealing part, an operation of forming a solder ball or a bump on the lower surface of the substrate 10 may be further performed.

By the operations described above, the electronic component module according to an exemplary embodiment of the present disclosure shown in FIG. 3 may be completed.

An order of the processes of the method of manufacturing the electronic component module according to an exemplary embodiment of the present disclosure is not limited.

That is, various applications may be made. For example, after the electronic components are mounted on the upper surface of the substrate, the sealing part may also be formed immediately thereon, and the connecting terminals (solder balls, or the like) may be formed during an operation of mounting the semiconductor chip in the cavity formed in a lower portion of the substrate.

Meanwhile, the electronic component module according to an exemplary embodiment of the present disclosure is not limited to the above-mentioned exemplary embodiment, but may be variously applied.

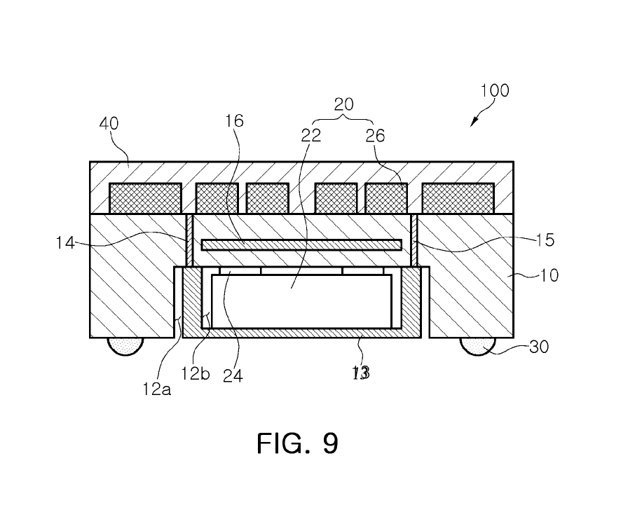

FIG. 9 is a cross-sectional view illustrating a cross-section of an electronic component module according to another exemplary embodiment of the present disclosure.

An electronic component module according to an exemplary embodiment of the present disclosure has a structure similar to that of the electronic component module 100 (see FIG. 1) according to the above-mentioned exemplary embodiment except for a structure of the heat radiating plate.

Accordingly, a detailed description of the same components will be omitted, and the structure of the heat radiating plate will be mainly described in more detail. In addition, the same reference numerals will be used to describe the same components as those in the above-mentioned exemplary embodiment.

Referring to FIG. 9, the electronic component module 100 according to another exemplary embodiment of the present disclosure may include the substrate 10 having a first cavity 12a formed therein, the heat radiating plate 13 having a second cavity 12b formed therein, and the electronic components 20.

The heat radiating plate 13 may have the second cavity 12b formed therein and may be disposed such that the first cavity 12a and the second cavity 12b of the substrate 10 are placed in opposite directions from each other.

Here, the semiconductor chip 22 described above may be seated in the second cavity 12b of the heat radiating plate 13 and may be inserted into the first cavity 12a of the substrate 10.

Alternatively, the heat radiating plate 13 may be inserted into the first cavity 12a after the semiconductor chip 22 is first connected to the substrate 10 by the flip-chip bonded part 24.

As such, heat generated from the semiconductor chip 22 may be more efficiently radiated by using the heat radiating plate 13 having the second cavity 12b formed therein, and since the semiconductor chip 22 may be surrounded by the cavity, the element interference and the electromagnetic wave interference between the electronic components 20 may be more reliably blocked.

As set forth above, according to exemplary embodiments of the present disclosure, the semiconductor chip is directly attached to the heat radiating plate, whereby heat generated from the semiconductor chip may be more efficiently radiated.

In addition, the wiring pattern is formed above the cavity, whereby the effects of the element interference and the electromagnetic wave interference between the electronic components may be significantly decreased.

While exemplary embodiments have been shown and described above, it will be apparent to those skilled in the art that modifications and variations could be made without departing from the spirit and scope of the present disclosure as defined by the appended claims.

What is claimed is:

1. An electronic component module, comprising:
a substrate including a cavity formed therein;
a heat radiating plate disposed on an opening of the cavity; and
an electronic component embedded in the cavity while being attached to one surface of the heat radiating plate.

2. The electronic component module of claim 1, wherein the electronic component is connected to an upper internal surface of the cavity by flip-chip bonding.

3. The electronic component module of claim 1, wherein the substrate includes a wiring pattern formed above the cavity.

4. The electronic component module of claim 1, wherein the substrate has at least one heat radiating via having one end electrically connected to the heat radiating plate and the other end exposed ouwardly of the substrate.

5. The electronic component module of claim 1, wherein the substrate is a ceramic substrate and the electronic component embedded in the cavity is a monolithic microwave integrated circuit (MMIC).

6. The electronic component module of claim 1, wherein the substrate includes at least one passive element mounted on an upper surface thereof.

7. The electronic component module of claim 6, wherein the substrate further includes a sealing part enclosing the passive element mounted on the upper surface of the substrate and covering an upper portion of the substrate.

8. An electronic component module, comprising:
a substrate including a first cavity formed therein;
a heat radiating plate including a second cavity formed therein and disposed such that the first cavity and the second cavity are placed in opposite directions from each other; and
an electronic component embedded in the second cavity and attached to one surface of the heat radiating plate.

9. The electronic component module of claim 8, wherein the electronic component is connected to one surface of the substrate by flip-chip bonding.

10. The electronic component module of claim 8, wherein the substrate includes a wiring pattern formed to be parallel to one surface of the electronic component.

11. The electronic component module of claim 8, wherein the substrate has at least one heat radiating via having one end electrically connected to the heat radiating plate and the other end exposed ouwardly of the substrate.

12. The electronic component module of claim 8, wherein the substrate is a ceramic substrate and the electronic component embedded in the cavity is a monolithic microwave integrated circuit (MMIC).

13. The electronic component module of claim 8, wherein the substrate includes at least one passive element mounted on an upper surface thereof.

14. The electronic component module of claim 13, wherein the substrate further includes a sealing part enclosing the passive element mounted on the upper surface of the substrate and covering an upper portion of the substrate.
